(19) United States
(12) Patent Application Publication
(10) Pub. No.: US 2019/0287915 A1
(43) Pub. Date: Sep. 19, 2019

(54) METHODS OF FORMING BARRIER STRUCTURES IN HIGH DENSITY PACKAGE SUBSTRATES

(71) Applicant: Intel Corporation, Santa Clara, CA (US)

(72) Inventors: David Unruh, Chandler, AZ (US); Srinivas V. Pietambaram, Gilbert, AZ (US)

(73) Assignee: Intel Corporation, Santa Clara, CA (US)

(21) Appl. No.: 16/464,995

(22) PCT Filed: Dec. 28, 2016
(86) PCT No.: PCT/US16/68942

§ 371 Date: May 29, 2019

(51) Int. Cl. H01L 23/532; H01L 23/522; H01L 21/768

(52) U.S. Cl. CPC H01L 23/53238; H01L 21/76841; H01L 23/5226

(57) ABSTRACT

Methods/structures of forming package structures are described. Those methods/structures may include forming a first conductive trace adjacent a second conductive trace on a dielectric material of a high density package substrate. A barrier layer is formed on at least one of the first conductive trace or the second conductive trace, wherein the barrier layer comprises a corrosion resistant material, and forming a conductive via on a portion of the barrier layer.

### BACKGROUND

Substrates for the next generation package devices, such as multi-chip packaging (MCP) substrates, require significantly higher density input/output (IO) routing. Achieving greater IO density requires optimization of such parameters as via size, line/space pitch, bump pitch, via-to-pad alignment, pad-to-via alignment, and material (e.g. resist and thin dielectric material) properties.

### BRIEF DESCRIPTION OF THE DRAWINGS

While the specification concludes with claims particularly pointing out and distinctly claiming certain embodiments, the advantages of these embodiments can be more readily ascertained from the following description when read in conjunction with the accompanying drawings in which:

FIGS. 1a-1h represent cross-sectional views of structures according to embodiments.

FIGS. 2a-2i represent cross sectional views of structures according to embodiments.

FIG. 3 represents a cross-sectional view of structures according to embodiments.

FIG. 4 represents a flow chart of a method according to embodiments.

FIG. 5 represents a cross sectional view of a computer system implementing one or more embodiments.

FIG. 6 represents a schematic of a computing device according to embodiments.

### DETAILED DESCRIPTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments.

The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views. The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. Layers and/or structures “adjacent” to one another may or may not have intervening structures/layers between them. A layer(s)/structure(s) that is/are directly on/directly in contact with another layer(s)/structure(s) may have no intervening layer(s)/structure(s) between them.

Various implementations of the embodiments herein may be formed or carried out on a substrate, such as a package substrate. A package substrate may comprise any suitable type of substrate capable of providing electrical communications between a die, such as an integrated circuit (IC) die, and a next-level component to which an IC package may be coupled (e.g., a circuit board). In another embodiment, the substrate may comprise any suitable type of substrate capable of providing electrical communication between an IC die and an upper IC package coupled with a lower IC/die package, and in a further embodiment a substrate may comprise any suitable type of substrate capable of providing electrical communication between an upper IC package and a next-level component to which an IC package is coupled.

A substrate may also provide structural support for a die/device, in the embodiments below. By way of example, in one embodiment, a substrate may comprise a multi-layer substrate—including alternating layers of a dielectric material and metal—built-up around a core layer (either a dielectric or a metal core). In another embodiment, a substrate may comprise a coreless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

A die/device may comprise any type of integrated circuit device. In one embodiment, the die may include a processing system (either single core or multi-core). For example, a die may comprise a microprocessor, a graphics processor, a signal processor, a network processor, a chipset, etc. In one embodiment, a die comprises a system-on-chip (SoC) having multiple functional units (e.g., one or more processing units, one or more graphics units, one or more communications units, one or more signal processing units, one or more security units, etc.). However, it should be understood that the disclosed embodiments are not limited to any particular type or class of device/die.

Embodiments of methods of forming packaging structures, such as forming a barrier layer on conductive traces disposed on/within a device substrate. Those methods/structures may include forming a first conductive trace adjacent a second conductive trace on a dielectric material of a package substrate. A barrier layer may be formed on at least one of the first conductive trace or the second conductive trace, wherein the barrier layer comprises a corrosion resistant material, and forming a conductive via on a portion of the barrier layer. The embodiments herein decrease within layer and layer to layer electromigration and oxidation of conductive traces in organic, high density package structures.

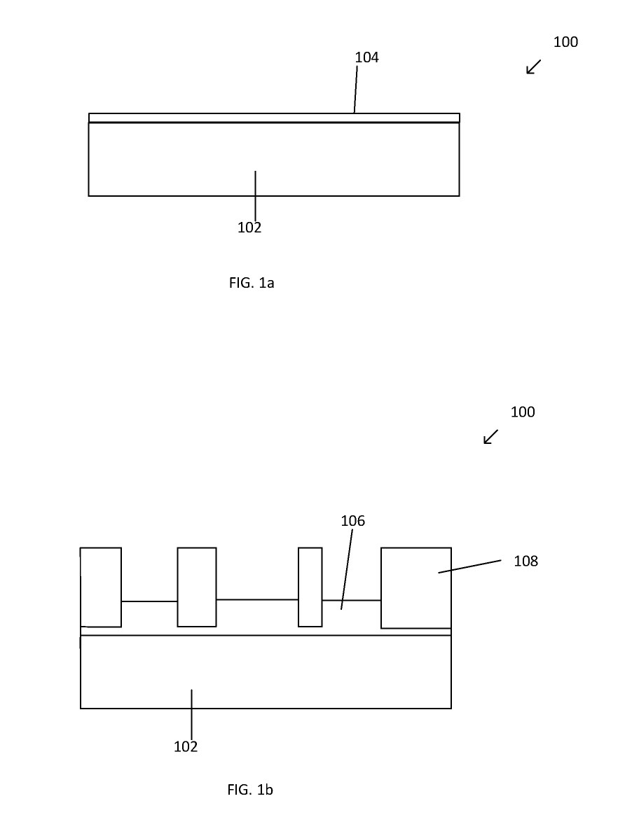

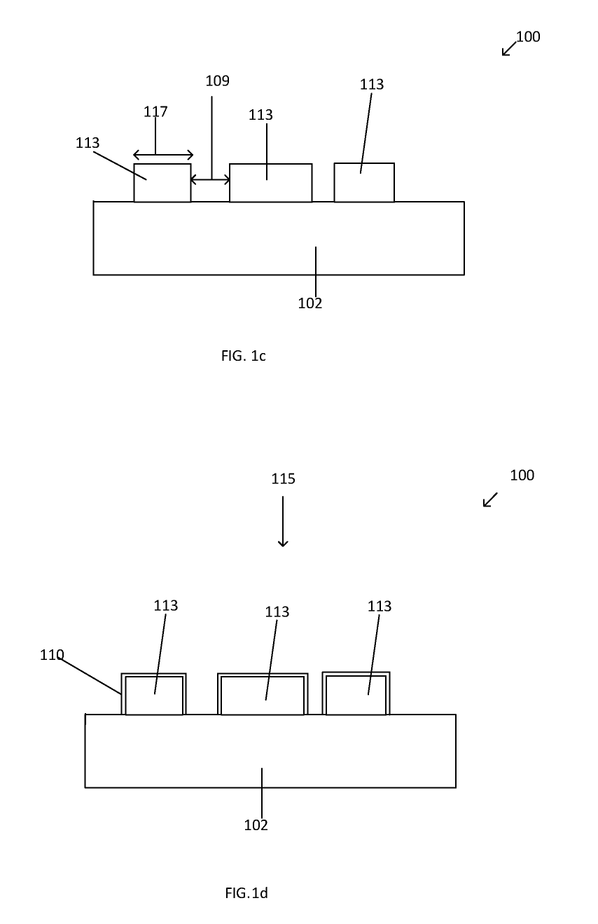

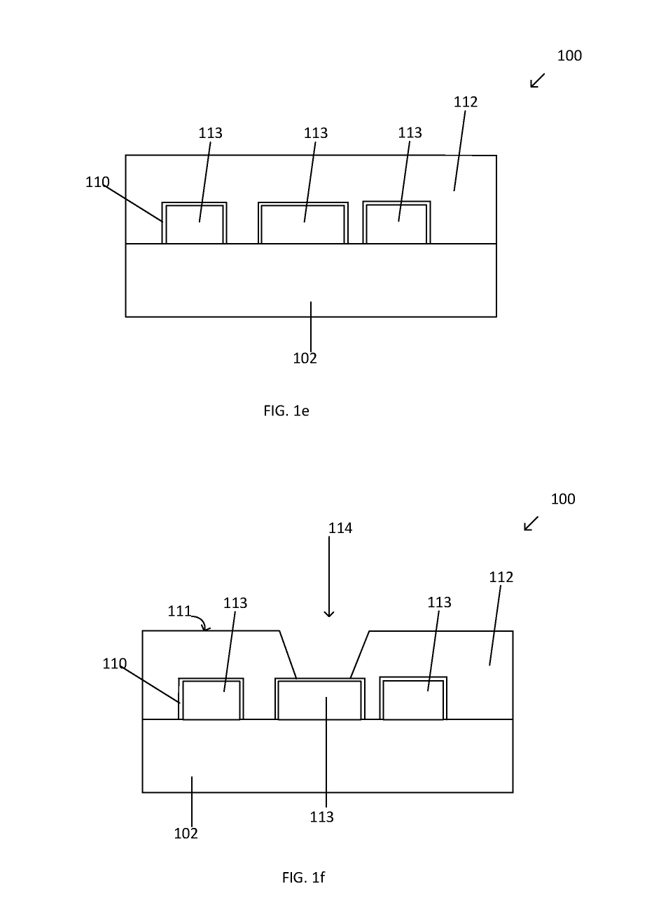

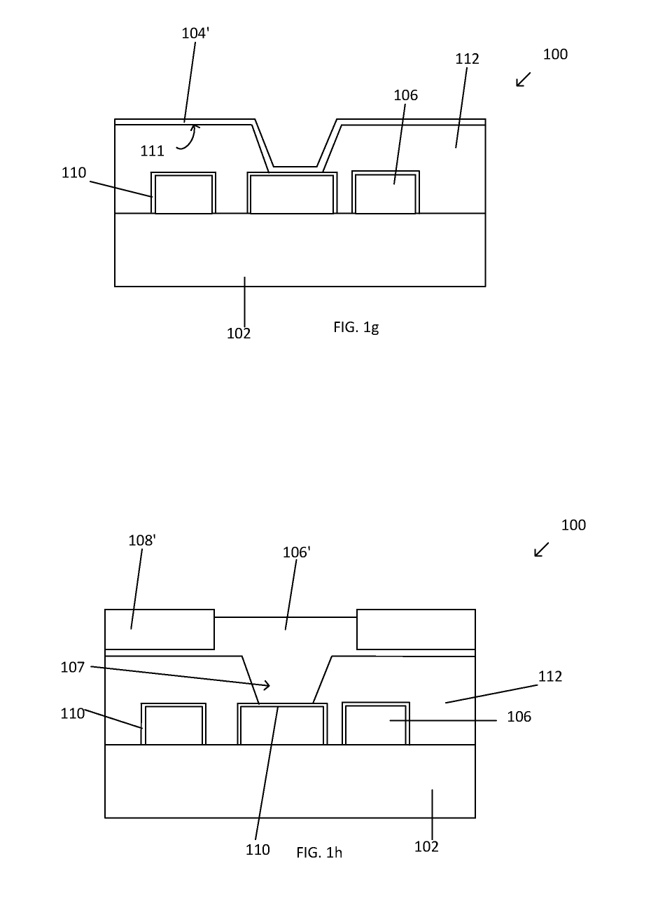

FIGS. 1a-1h illustrate cross-sectional views of embodiments of fabricating a barrier layer on fine pitched traces in a very high density (VHD) substrate. In FIG. 1a, a top view of a portion of package structure 100 is shown, which may comprise a dielectric material 102. In an embodiment, the portion of the package structure 100 may comprise a portion of an organic substrate/interposer. The package substrate 100 may comprise any suitable substrate 100 materials, such as but not limited to dielectric and conductive materials, for example. A seed layer 104 may be formed on a top surface of the substrate 100. In an embodiment, the seed layer 104 may comprise a conductive material, such as copper, for example. In FIG. 1b, a patterning material 108, such as a resist material, for example, may be formed on portions of the seed layer 104. A conductive layer 106, such as a metal layer, may be formed on the seed layer 104 (not shown in FIG. 1b, wherein the seed layer 104 may be subsumed in the conductive layer 106, in an embodiment). In an embodiment, the conductive layer 106 may be formed using any formation technique, such as by electroplating, physical deposition, and electroless deposition techniques, for example.

In an embodiment, a portion of the conductive layer 106 may be patterned and etched to form at least one conductive trace 113 (FIG. 1c). In another embodiment, an adhesion promoter may be applied to the conductive layer 106. In another embodiment, the conductive layer 106 may be roughened. The at least one conductive trace 113 may comprise a line spacing/pitch 109 between individual ones of the conductive traces 113. In an embodiment, the spacing 109 may comprise a very fine, high density spacing 113 between adjacent conductive traces 113, wherein the at least one conductive traces 113 may comprise a portion of a very high density organic package 100. In an embodiment, the spacing 109 may comprise between about 2 microns and about 20 microns). In another embodiment, the spacing 109 may comprise between about 1 micron and about 5 microns, in other embodiments the spacing may be between about 1 micron and 10 microns. In an embodiment, a width 117 of the at least one conductive trace 113 may comprise between about 2 microns and about 20 microns. In another embodiment, the width 117 may comprise between about 1 micron and about 5 microns.

A barrier layer/material 110 may be formed on the at least one conductive trace 113 (FIG. 1d). In an embodiment, the barrier layer 110 may be formed on at least one of a first conductive trace 113 and/or a second conductive trace 113, wherein the first and second conductive traces are adjacent one another. In an embodiment, the barrier layer 110 may be formed on the at least one conductive trace 113 by using a plating process, such as by employing a selective electroless plating process 115, for example. In an embodiment, the barrier layer 110 may comprise noble metals such as gold, silver, platinum, palladium, ruthenium, rhodium and their alloys. In an embodiment, the barrier material 110 may comprise at least one of nickel, phosphorus, ruthenium, cobalt, tungsten, or copper and their alloys. In an embodiment, the barrier material 110 may comprise a nickel phosphorus material that is doped with a noble metal, such as gold or silver. In an embodiment, the electroless plating process 115 may be optimized in order to improve the electromigration resistance of the barrier layer 110. In an embodiment, the barrier material 110 may comprise a thickness of between about 20 nm to about 300 nm. In an embodiment, the barrier material 110 may comprise a metal that is more noble (i.e. less susceptible to corrosion in air) than copper (such as silver, palladium, or gold, for example) that will protect a copper trace 113 from oxidizing, rendering the trace 113 more resistant to migrating into a surrounding dielectric material. The barrier material, which may comprise metals/alloys, can be selectively deposited on the traces 113 by using any suitable electroless plating process 115.

In an embodiment, the electroless deposition process 115 of metals and/or their alloys may be selectively deposited on the conductive traces 113 to address performance and reliability needs of the package. The specific metal/alloys selected for the barrier material 110 may depend on the specific application. In some cases, dielectric films that may be utilized within the package substrate 100 may create a risk for a particular conductive layer to exhibit electrochemical migration, which can lead to shorting due to the effects of material from the conductive trace 113, such as copper, diffusing into such a dielectric material 112 (as in FIG. 1e, for example), which may be subsequently formed on the barrier material 110. In an embodiment the dielectric material 112 may comprise a pre-preg material of a package substrate, and may be placed/formed/laminated on the barrier material 110. In another embodiment the dielectric material 112 may comprise High Density Interconnect (HDI) build-up dielectric material (Ajinomoto Build-up Film, ABF, for example) of a package substrate, and may be placed/formed/laminated on the barrier material 110.

For example, copper atoms and ions from the at least one conductive trace 113 can diffuse into the surrounding dielectric material 112 as a function of electrical field, humidity and temperature, which may then shorten the time to failure for very high density substrate packages such as package substrate 100. By incorporating a conformal electroless barrier layer 110, which may comprise a more noble metal than copper, such as silver, palladium, gold, or their alloys, in an embodiment, a conductive trace may be protected from electrochemical migration, thus extending the time to failure of the substrate package. In an embodiment, within layer electrochemical migration of the conductive trace 113 material into the surrounding/adjacent dielectric material 112, can be prevented by selectively forming a more noble metal than the conductive trace 113 material conformally on top of the conductive traces 113, which enables the prevention of the degradation of the conductive trace 113 through copper oxidation, for example.

In another embodiment, the barrier layer/material 110 may comprise a concentration of about 1 percent to about 5 percent tungsten, molybdenum and/or ruthenium, for example, about 2-5 percent phosphorus, and a balance of about 90 to about 97 percent nickel, in an embodiment. In an embodiment, the barrier material 110 may comprise a nickel/phosphorus film that may be alloyed with a refractory metal in a desired compositional range, depending upon the particular design needs. For example, the refractory metal may include, but is not limited to, tungsten, molybdenum, and ruthenium. In one embodiment, a refractory metal content of between about 2 and 12% by weight may be used in the barrier material 110.

For example, for a refractory metal content of between about 2 and 12% by weight, the barrier material 110 may comprise a phosphorus content of between about 2 and 12% by weight with the remainder being nickel. In one embodiment, the refractory metal may comprise tungsten, wherein the barrier material 110 may comprise a tungsten content of between about 2 and 6% by weight and a phosphorus content of between about 3 and 6% by weight, with the remainder being nickel. In another embodiment, the barrier material 110 may comprise a tungsten content of between about 5 and 6% by weight, and a phosphorus content of between about 5 and 6% by weight, with the remainder being nickel.

The barrier material 110 of the embodiments herein provide strong electro-migration resistance, superior corrosion resistance, and higher thermal endurance,

In an embodiment, the refractory metal and phosphorus compositions may be optimized, by optimizing the appropriate doping levels and/or adjusting the thickness of the barrier material/layer 110 to achieve a desired combination of properties for both high and low power applications.

In an embodiment, the barrier material 110 comprises an electroless plated coating of any suitable barrier metal and/or its alloys, to prevent layer to layer (such as between a first level and a second level of metal traces within a substrate, for example) electromigration. In an embodiment, the barrier material 110 may comprise metal/metal alloys, such as cobalt/nickel based alloys that may be formed using standard packaging electro-less equipment. The specific metals/alloys that may be used for the barrier material 110 formation may vary depending upon the specific application. In an embodiment, the barrier layer 113 may be deposited in one step (such as in a single formation process) or may be formed utilizing a sequential process, such as by forming a first barrier material (such as nickel or cobalt) on top of the at least one conductive trace 113 initially, and then forming/alloying a second barrier layer (such as gold) 113 on top of the first barrier layer.

Since the barrier material 110 is conductive, it allows for the subsequent build-up of layers of the package substrate 100 without partial removal of the barrier 110. In an embodiment, the use of electroless metal barrier structures in the routing of high 10 density packaging serves to increase the electromigration resistance of the at least one conductive trace 113. In some cases decreased line widths, required for such high density packaging, may generate higher current densities, which may result in a higher risk of failure due to electromigration, thus the barrier materials of the embodiments herein reduce electromigration failures in the high density packaging structures of the various embodiments.

In an embodiment, a very high density package structure/substrate, such as package structure 100, may comprise greater than about 100 I/O/mm/layer. Such a package structure may drive higher current density in the substrate conductive interconnects, and may result in higher risk of reliability issues resulting from within layer electromigration (such as in the degradation of conductive traces through diffusion of metal atoms and ions into the dielectric under high humidity and high temperature conditions), and layer to layer electromigration (such as in the migration of atoms within a conductive trace due to an electron wind). In the case of copper, diffusion effects of copper traces into a surrounding dielectric material may be caused by localized copper oxidation.

Returning back to FIG. 1f, an opening 114 is depicted that may be formed in the dielectric material 112, wherein a portion of the barrier material 110 disposed on at least one of the conductive traces 113 may be exposed. In an embodiment, the opening 114 may be formed by utilizing a laser process, such as a laser drilling process, for example, but any suitable process may be employed with which to form the opening 114. In an embodiment, a second seed layer 104′, may be formed on the exposed portion of the barrier material 110, and may also be formed on a surface/top portion 111 of the dielectric material 112 (FIG. 1g).

A second conductive layer 106′, may be formed/plated onto the second seed layer 104′, wherein the second conductive layer 106′ may comprise a copper layer, in an embodiment, but may comprise any other suitable conductive materials, according to the particular application. In an embodiment, the package substrate 100 may comprise an organic high density package interposer (FIG. 1h). The second conductive layer 106′ may be patterned with a patterning material 108′, and may be etched to form a via structure 107, wherein the via 107 may serves to couple a first level of metal and a second level of metal within the dielectric material 112 of the package substrate 100, in an embodiment. The presence of the barrier layer 110 between the via 107 and the at least one conductive trace 113 serves to reduce/eliminate diffusion of the copper/metal of the conductive trace 113 into the surrounding dielectric material 112, as well as between the conductive trace 113 and the via material 107.

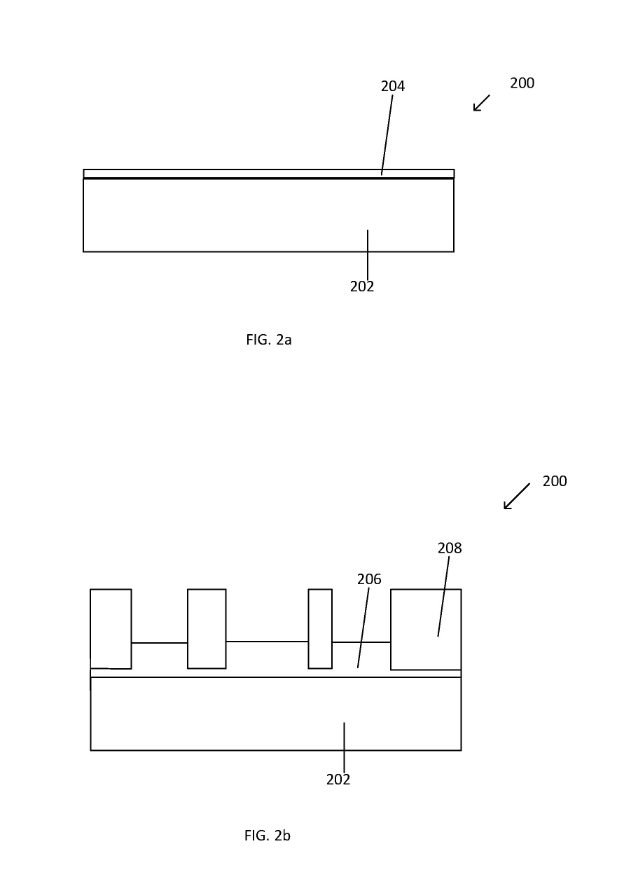

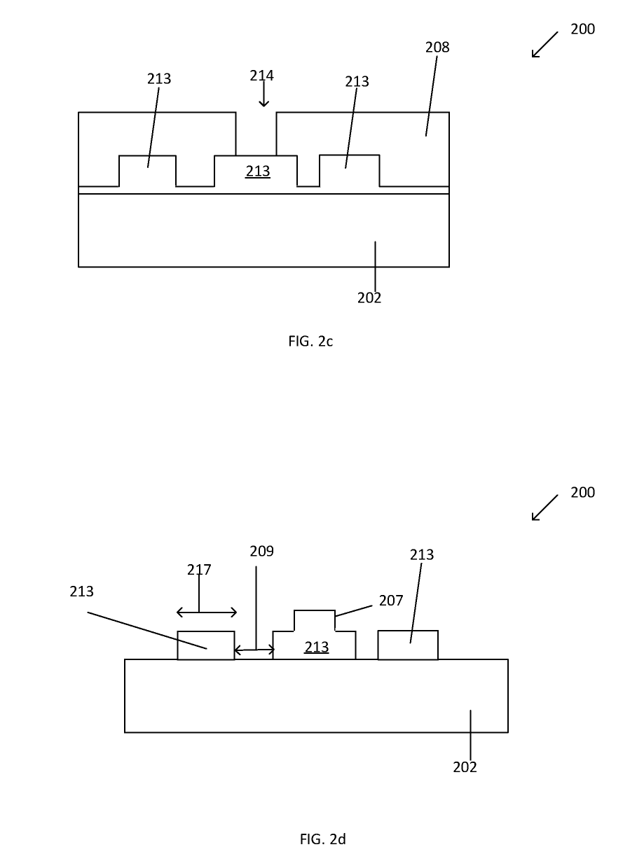

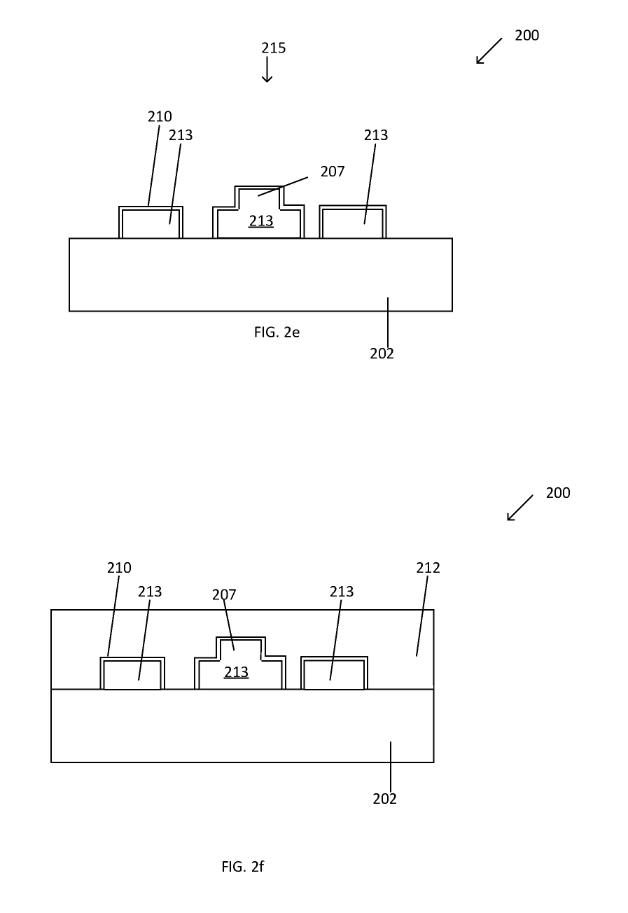

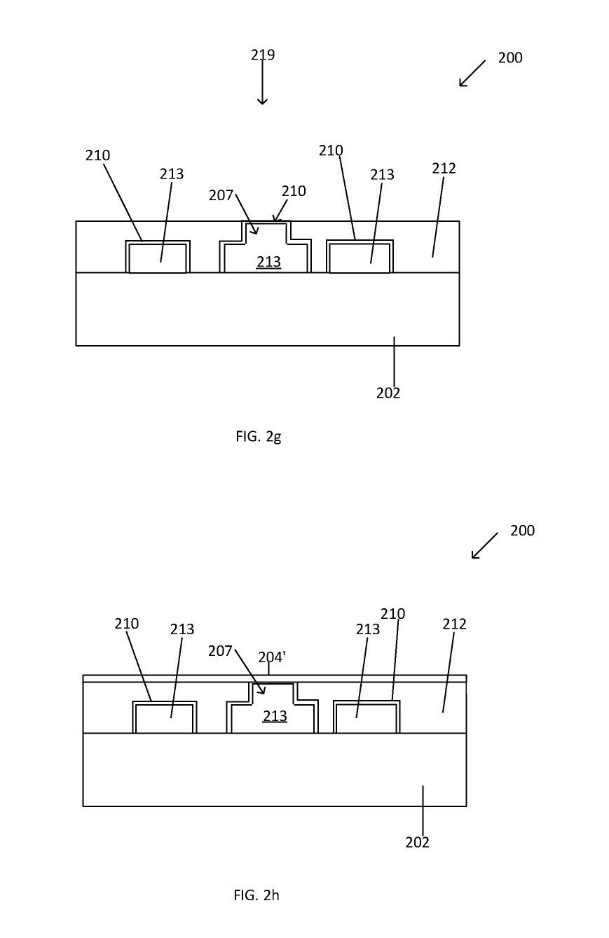

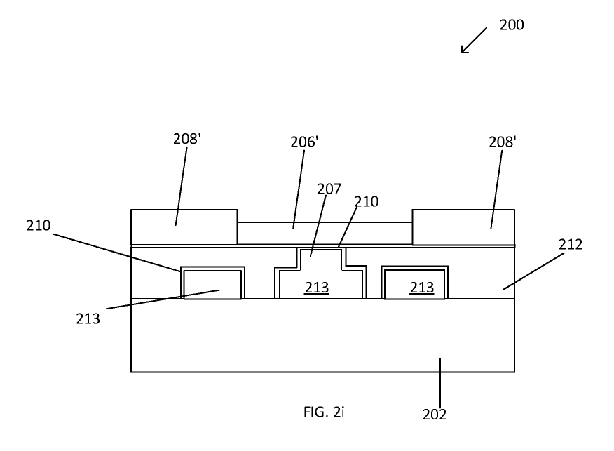

In another embodiment, a conductive layer/material 206 may be formed on a seed layer 204 disposed on a dielectric material 202 of a package substrate 200, and may be patterned with a resist material (FIGS. 2a-2b), (similar to FIGS. 1a-1b) to form at least one conductive trace 213 (FIG. 2c). A via structure 207 may be formed on at least one conductive trace 213, utilizing any suitable patterning and etching techniques (FIGS. 2c-2d). In an embodiment, line spacing 209 and line widths 209 of the conductive traces 113 may comprise very fine line/space dimensions, and in an embodiment may comprise between 1 micron to about 5 micron line/space dimensions. A barrier material 210 may be selectively formed, utilizing an electroless plating process 215, on the at least one conductive trace 213, and on the via structure 207 (FIG. 2e). A dielectric material 212 may be formed/laminated on the barrier material 210 (FIG. 20. A portion of the dielectric layer 212 may be planarized/removed, utilizing a planarization process 219, such as a chemical mechanical polishing process (CMP), for example, to expose a top surface of the barrier material 210 that is disposed on the via structure 207 (FIG. 2g).

A seed layer 204′ may be formed using any suitable process, on the exposed barrier material 210, and on a top surface of the dielectric material 212 (FIG. 2h). In an embodiment, a second level of conductive material 206′ may be formed on the seed layer 204′ (FIG. 2i). A patterning material 208′, such as a resist material, may be adjacent the second level of conductive material 206′. The barrier material 210 may be disposed between the via 207 and the second metal layer 206′, and may serve to prevent electromigration and/or diffusion of the conductive material (such as copper, for example) of the via 207, into the dielectric material 212, and/or into the second level of conductive material 206′.

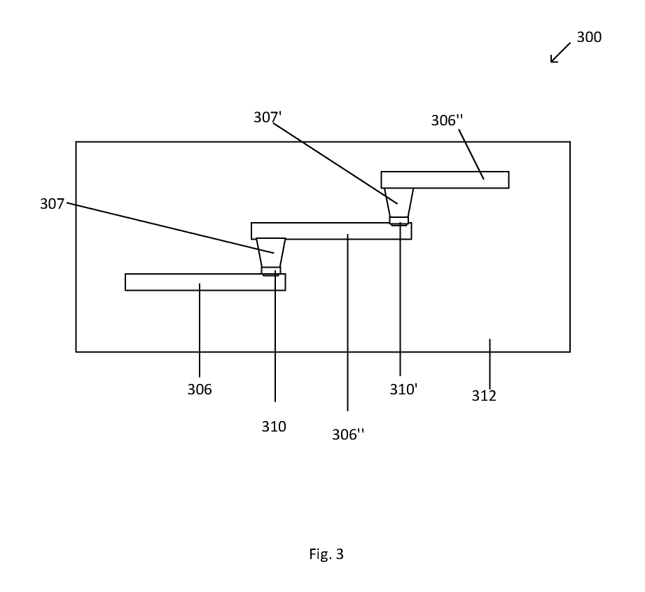

FIG. 3 depicts multiple levels of metal within a VHD package substrate 300. A first level of metal 306 may be disposed in the dielectric material 312 of the package substrate 300, wherein a first barrier material 310 may be disposed between a first via 307 and a second level of metal 306′. A second barrier material 310′ may be disposed between a second via 307′ and a third level of metal 306″. In an embodiment, first and second levels of conductive material 306, 306′, may comprise metal materials such as copper, for example. The package substrate 300 may comprise greater than about 100 I/O per millimeter per layer of metal, in an embodiment. In an embodiment, the package substrate 300 may comprise conductive trace/line spacing of about 1 micron to about 5 microns, and conductive trace/line widths of about 1 micron to about 5 microns. In an embodiment, the barrier material 310 may comprise a thickness of between about 20 nm to about 300 nm. In an embodiment, the portion of the substrate 300 may comprise an organic package substrate, and may further comprise a portion of a multi-chip package substrate.

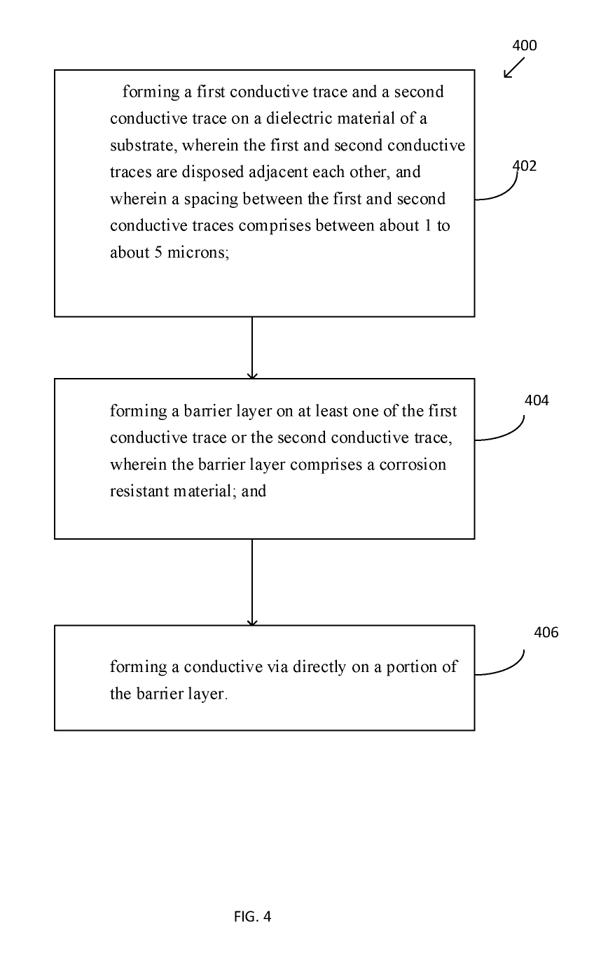

FIG. 4 depicts a method 400 according to embodiments herein. At step 402, a first conductive trace and a second conductive trace are formed on a dielectric material of a substrate, wherein the first and second conductive traces are disposed adjacent each other, and wherein a spacing between the first and second conductive traces comprises between about 1 micron to about 5 microns. In an embodiment, the substrate may comprise a very high density substrate package, wherein the conductive traces may comprise a width of about 1 micron to about 5 microns, and wherein the number of I/O's are greater than about 100 per millimeter per metal level.

At step 404, a barrier layer may be formed on at least one of the first conductive trace or the second conductive trace, wherein the barrier layer comprises a corrosion resistant material. In an embodiment, the barrier material may be selected from the group consisting of nickel, phosphorus, ruthenium, cobalt, tungsten, copper, silver, platinum, palladium, gold, rhodium or ruthenium. In an embodiment, the barrier material may comprise a thickness of about 20 nm to about 300 nm, and may be formed by an electroless deposition. At step 406, a conductive via may be formed on at least one of the first and second traces. In an embodiment, at least one die may be disposed on a top surface of the substrate, wherein the substrate may comprise an organic substrate, and wherein the at least one die may be electrically coupled with the barrier layer.

The structures of the embodiments herein may be coupled with any suitable type of structures capable of providing electrical communications between a microelectronic device, such as a die, disposed in package structures, and a next-level component to which the package structures herein may be coupled (e.g., a circuit board). The device/package structures, and the components thereof, of the embodiments herein may comprise circuitry elements such as logic circuitry for use in a processor die, for example. Metallization layers and insulating material may be included in the structures herein, as well as conductive contacts/bumps that may couple metal layers/interconnects to external devices/layers. In some embodiments the structures may further comprise a plurality of dies, which may be stacked upon one another, depending upon the particular embodiment. In an embodiment, a die(s) may be partially or fully embedded in a package structure.

The various embodiments of the device structures included herein may be used for system on a chip (SOC) products, and may find application in such devices as smart phones, notebooks, tablets, wearable devices and other electronic mobile devices. In various implementations, the package structures herein may be included in a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder, and wearable devices. In further implementations, the package devices herein may be included in any other electronic devices that process data.

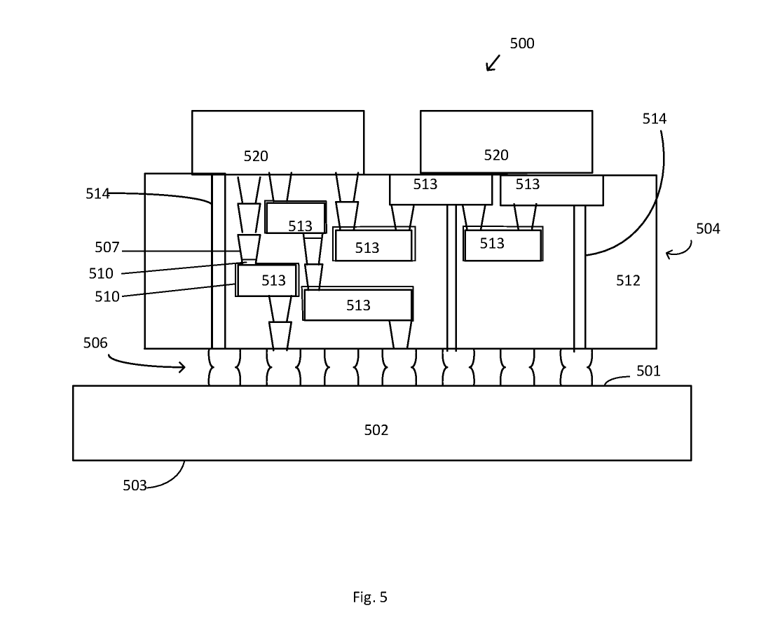

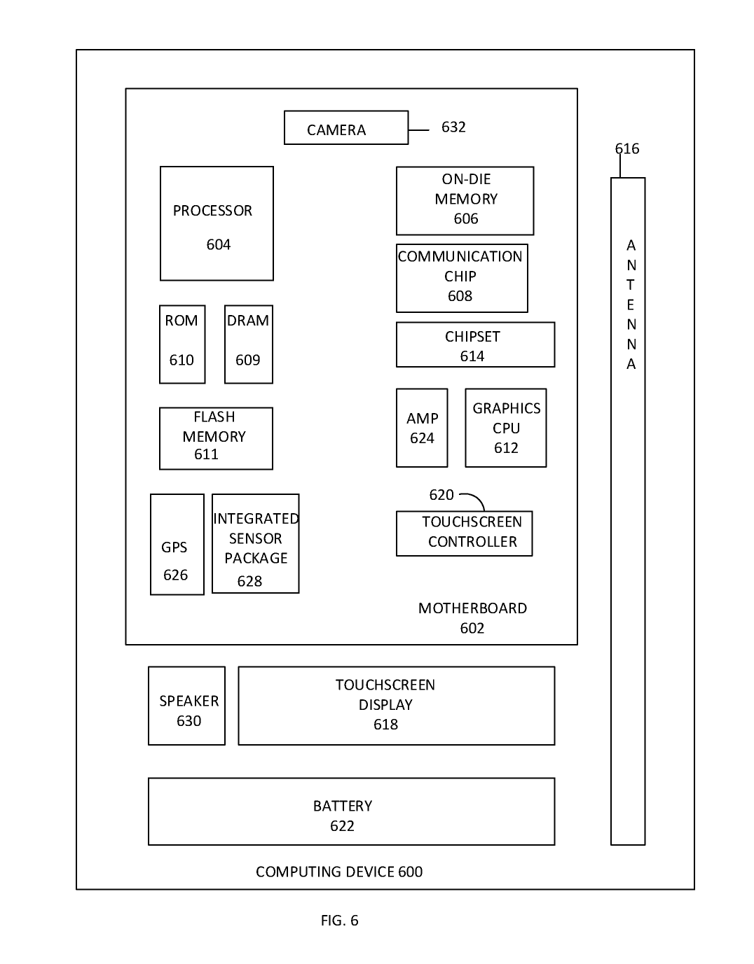

Turning now to FIG. 5, illustrated is an embodiment of a computing system 500. The system 500 includes a mainboard 502 or other circuit board. Mainboard 502 includes a first side 501 and an opposing second side 503, and various components may be disposed on either one or both of the first and second sides 501, 503. In the illustrated embodiment, the computing system 500 includes at least one die 520, disposed on a surface (such as on a top or bottom or side surface) of the substrate 504, such as a package substrate comprising the barrier material of the various embodiments herein. The substrate 504 may comprise an interposer 504, for example.

The substrate 504 may comprise various levels of conductive layers 513, for example, which may be electrically and physically connected to each other by via structures 507. The conductive layers 513 may comprise conductive traces in an embodiment, which may comprise very high density routing structures, and may comprise line and space widths of between about 1 micron to about 5 microns. The conductive layers 513 may comprise a barrier material 510 (similar to the barrier material of FIG. 1h for example), on any of their surfaces, such as on a bottom, top and/or side surface. The via structures 507 may comprise a barrier material 510 (similar to the barrier material of FIG. 3 for example) between the via 507 and the at least one conductive layer 513, in some embodiments. In an embodiment, the least one die 520 may be electrically/conductively coupled with the barrier layer 510.

The substrate 504 may further comprise through substrate vias 514. Dielectric material 512 may separate/isolate conductive layers from each other within the substrate 504. Joint structures 506 may electrically and physically couple the substrate 504 to the board 502. The computing system 500 may comprise any of the embodiments described herein. In an embodiment, the substrate may comprise a VHD organic substrate, and may comprise a multi-chip package substrate in an embodiment.

System 500 may comprise any type of computing system, such as, for example, a hand-held or mobile computing device (e.g., a cell phone, a smart phone, a mobile interne device, a music player, a tablet computer, a laptop computer, a net top computer, etc.). However, the disclosed embodiments are not limited to hand-held and other mobile computing devices and these embodiments may find application in other types of computing systems, such as desk-top computers and servers.

Mainboard 502 may comprise any suitable type of circuit board or other substrate capable of providing electrical communication between one or more of the various components disposed on the board. In one embodiment, for example, the mainboard 502 comprises a printed circuit board (PCB) comprising multiple metal layers separated from one another by a layer of dielectric material and interconnected by electrically conductive vias. Any one or more of the metal layers may be formed in a desired circuit pattern to route—perhaps in conjunction with other metal layers—electrical signals between the components coupled with the board 501. However, it should be understood that the disclosed embodiments are not limited to the above-described PCB and, further, that mainboard 501 may comprise any other suitable substrate.

FIG. 6 is a schematic of a computing device 600 that may be implemented incorporating embodiments of the package structures described herein. For example, any suitable ones of the components of the computing device 600 may include, or be included in, package structures comprising the barrier layer/material of the various embodiments disclosed herein. In an embodiment, the computing device 600 houses a board 602, such as a motherboard 602 for example. The board 602 may include a number of components, including but not limited to a processor 604, an on-die memory 606, and at least one communication chip 608. The processor 604 may be physically and electrically coupled to the board 602. In some implementations the at least one communication chip 608 may be physically and electrically coupled to the board 602. In further implementations, the communication chip 608 is part of the processor 604.

Depending on its applications, computing device 600 may include other components that may or may not be physically and electrically coupled to the board 602, and may or may not be communicatively coupled to each other. These other components include, but are not limited to, volatile memory (e.g., DRAM) 609, non-volatile memory (e.g., ROM) 610, flash memory 611, a graphics processor unit (GPU) 612, a chipset 614, an antenna 616, a display 618 such as a touchscreen display, a touchscreen controller 620, a battery 622, an audio codec (not shown), a video codec (not shown), a global positioning system (GPS) device 626, an integrated sensor 628, a speaker 630, a camera 632, an amplifier 624, compact disk (CD) (not shown), digital versatile disk (DVD) (not shown), and so forth). These components may be connected to the system board 602, mounted to the system board, or combined with any of the other components.

The communication chip 608 enables wireless and/or wired communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 608 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond.

The computing device 600 may include a plurality of communication chips 608. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. The term “processor” may refer to any device or portion of a device that processes electronic data from registers and/or memory to transform that electronic data into other electronic data that may be stored in registers and/or memory.

In various implementations, the computing device 600 may be a laptop, a netbook, a notebook, an ultrabook, a smartphone, a tablet, a personal digital assistant (PDA), an ultra-mobile PC, a wearable device, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Embodiments of the package structures described herein may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

### EXAMPLES

Example 1 is a microelectronic package structure comprising a package substrate comprising a dielectric material, a first conductive trace disposed adjacent a second conductive trace, wherein the first and second conductive traces are disposed on the dielectric material, a barrier layer directly on at least one of the first conductive trace or the second conductive trace, wherein the barrier layer comprises a corrosion resistant material; and a conductive via on a portion of the barrier layer.

Example 2 includes the microelectronic package structure of claim 1, wherein a spacing between the first and second conductive traces is between about 1 micron to about 5 microns. Example 3 includes the microelectronic package structure of claim 1 wherein a width of at least one of the first or second conductive traces is between about 1 to about 5 microns.

Example 4 includes the microelectronic package structure of claim 1 wherein the barrier layer comprises a material that is more noble than copper.

Example 5 includes the microelectronic package structure of claim 1 wherein the barrier layer comprises at least one of nickel, phosphorus, ruthenium, cobalt, tungsten, copper, silver, platinum, palladium, gold, rhodium or ruthenium and alloys thereof.

Example 6 includes the microelectronic package structure of claim 1 wherein the barrier layer comprises a thickness of about 20 nm to about 300 nm.

Example 7 includes the microelectronic package structure of claim 1 wherein the barrier comprises a selectively deposited electroless metal.

Example 8 includes the microelectronic package structure of claim 1 wherein the package structure comprises a portion of a multi-chip package, wherein at least one die is conductively coupled to the barrier layer.

Example 9 is a microelectronic package structure comprising: a package substrate comprising a first conductive trace and a second conductive trace, wherein a spacing between the first and second trace is between about 1 micron and 10 microns, a barrier layer on at least one of the first conductive trace or the second conductive trace, wherein the barrier layer comprises a corrosion resistant material; and at least one die on a top surface of the package substrate, wherein the at least one die is electrically coupled with the barrier layer.

Example 10 includes the microelectronic package structure of claim 9 wherein the barrier layer comprises an electroless plated material.

Example 11 includes the microelectronic package structure of claim 9 wherein the barrier layer comprises between about 20 nm to about 300 nm in thickness.

Example 12 includes the microelectronic package structure of claim 9 wherein the substrate comprises an organic substrate.

Example 13 includes the microelectronic package structure of claim 9 wherein the barrier layer further comprises a via structure directly physically coupled to the barrier layer.

Example 14 includes the microelectronic package structure of claim 9 wherein the barrier metal comprises a first barrier material disposed on a second barrier material.

Example 15 includes the microelectronic package structure of claim 14 wherein the first barrier material comprises one of cobalt or nickel and the second barrier material comprises one of gold or silver.

Example 16 includes the microelectronic package structure of claim 9, wherein an I/O routing density is greater than about 100 I/O per millimeter per layer.

Example 17 is a method of forming a microelectronic package structure, comprising: forming a first conductive trace and a second conductive trace on a dielectric material of a substrate, wherein the first and second conductive traces are disposed adjacent each other, and wherein a spacing between the first and second conductive traces comprises between about 1 micron to about 5 microns, forming a barrier layer on at least one of the first conductive trace or the second conductive trace, wherein the barrier layer comprises a corrosion resistant material; and forming a conductive via directly on a portion of the barrier layer.

Example 18 includes the method of claim 17 further comprising wherein the barrier material is formed by electroless plating.

Example 19 includes the method of claim 17 wherein the barrier material is selectively formed on at least one of the first and second conductive traces, and comprises a thickness of between about 20 nm and about 300 nm.

Example 20 includes the method of claim 17 further comprising wherein the package substrate comprises at least 100 I/O per millimeter per level of metal.

Example 21 includes the method of claim 17 wherein at least one die is electrically coupled to the barrier material.

Example 22 includes the method of claim 17 further comprising wherein the trace comprises a copper material, and wherein the barrier material is formed by forming an alloy with the copper material.

Example 23 includes the method of claim 17 further comprising wherein the barrier material is formed by forming an electromigration resistant layer on at least one of the conductive traces, wherein the electromigration resistant layer comprises at least one of nickel, phosphorus, ruthenium, cobalt, tungsten, copper, silver, platinum, palladium, gold, rhodium or ruthenium and/or alloys thereof.

Example 24 includes the method of claim 17 further comprising wherein the package substrate comprises a multi-chip package structure.

Example 25 includes the method of claim 17 wherein the barrier material is formed by forming a first barrier material on the conductive trace, and then forming a second barrier material on the first barrier material, wherein the barrier material comprises a thickness of between about 20 nm and about 300 nm.

Example 26 includes the microelectronic package structure of example 9 further comprising a system comprising: a communication chip communicatively coupled to the microelectronic structure; and a DRAM communicatively coupled to the communication chip.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus the embodiments are not limited to the structures described herein.

1-25. (canceled)

26. A microelectronic package structure comprising:
a package substrate comprising a dielectric material;
a first conductive trace disposed adjacent a second conductive trace, wherein the first and second conductive traces are disposed on the dielectric material;
a barrier layer directly on at least one of the first conductive trace or the second conductive trace, wherein the barrier layer comprises a corrosion resistant material; and
a conductive via on a portion of the barrier layer.

27. The microelectronic package structure of claim 26, wherein a spacing between the first and second conductive traces is between about 1 micron to about 5 microns.

28. The microelectronic package structure of claim 26, wherein a width of at least one the first or second conductive traces is between about 1 micron to about 5 microns.

29. The microelectronic package structure of claim 26, wherein the barrier layer comprises a material that is more noble than copper.

30. The microelectronic package structure of claim 26, wherein the barrier layer comprises at least one of nickel, phosphorus, ruthenium, cobalt, tungsten, copper, silver, platinum, palladium, gold, rhodium or ruthenium or alloys thereof.

31. The microelectronic package structure of claim 26, wherein the barrier layer comprises a thickness of about 20 nm to about 300 nm.

32. The microelectronic package structure of claim 26, wherein the barrier layer comprises a selectively deposited electroless metal.

33. The microelectronic package structure of claim 26, wherein the package structure comprises a portion of a multi-chip package, wherein at least one die is conductively coupled to the barrier layer.

34. A microelectronic package structure comprising:
a package substrate comprising a first conductive trace and a second conductive trace, wherein a spacing between the first and second conductive trace is between about 1 micron and about 10 microns;
a barrier layer on at least one of the first conductive trace and the second conductive trace, wherein the barrier layer comprises a corrosion resistant material; and
at least one die on a top surface of the package substrate, wherein the at least one die is electrically coupled with the barrier layer.

35. The microelectronic package structure of claim 34, wherein the barrier layer comprises an electroless plated material.

36. The microelectronic package structure of claim 34, wherein the barrier layer comprises between about 20 nm to about 300 nm in thickness.

37. The microelectronic package structure of claim 34, wherein the package substrate comprises an organic substrate.

38. The microelectronic package structure of claim 34, wherein the barrier layer further comprises a via structure physically coupled to the barrier layer.

39. The microelectronic package structure of claim 34, wherein the barrier layer comprises a first barrier layer disposed on a second barrier layer.

40. The microelectronic package structure of claim 39, wherein the first barrier material comprises one of cobalt or nickel and the second barrier material comprises one of gold or silver.

41. The microelectronic package structure of claim 34, wherein an I/O routing density is greater than about 100 I/O per millimeter per metal layer.

42. A method of forming a microelectronic package structure, comprising:
forming a first conductive trace and a second conductive trace on a dielectric material of a substrate, wherein the first and second conductive traces are disposed adjacent each other, and wherein a spacing between the first and second conductive traces comprises between about 1 micron to about 5 microns;
forming a barrier layer on at least one of the first conductive trace or the second conductive trace, wherein the barrier layer comprises a corrosion resistant material; and
forming a conductive via directly on a portion of the barrier layer.

43. The method of claim 42 further comprising wherein the barrier layer is formed by electroless plating.

44. The method of claim 42, wherein the barrier layer is selectively formed on at least one of the first and second conductive traces, and comprises a thickness of between about 20 nm and about 300 nm.

45. The method of claim 42 further comprising wherein the substrate comprises at least 100 I/O per millimeter per a level of metal in the substrate.

46. The method of claim 42, wherein at least one die is electrically coupled to the barrier layer.

47. The method of claim 42 further comprising wherein at least one of the first or second conductive trace comprises a copper material, and wherein the barrier layer is formed by selectively forming a conductive alloy on the copper material.

48. The method of claim 42 further comprising wherein the barrier layer is formed by forming an electromigration resistant layer on at least one of the first or second conductive traces, wherein the electromigration resistant layer comprises at least one of nickel, phosphorus, ruthenium, cobalt, tungsten, copper, silver, platinum, palladium, gold, rhodium or ruthenium or alloys thereof.

49. The method of claim 42 further comprising wherein the barrier layer comprises nickel, tungsten and phosphorus.

50. The method of claim 42, wherein the barrier layer is formed by forming a first barrier material on the conductive trace, and then forming a second barrier material on the first barrier material.
